(19) United States
(12) Patent Application Publication
(10) Pub. No.: US 2011/0243171 A1
(43) Pub. Date: Oct. 6, 2011

(54) NITRIDE-BASED SEMICONDUCTOR LASER DEVICE

(75) Inventor: Takashi Kano, Hirakata-shi (JP)

(73) Assignee: Sanyo Electric Co., Ltd., Moriguchi-shi (JP)

(21) Appl. No.: 13/069,950

(22) Filed: Mar. 23, 2011

(30) Foreign Application Priority Data
Mar. 30, 2010 (JP) 2010-77201

(51) Int. Cl. H01S 5/343

(52) U.S. Cl. 372/45.011

(57) ABSTRACT

This nitride-based semiconductor laser device includes an active layer made of a nitride-based semiconductor and a p-type cladding layer, made of a nitride-based semiconductor, formed on the active layer. The refractive index in a region of the p-type cladding layer closer to the active layer is lower than the refractive index in another region of the p-type cladding layer opposite to the active layer.

### CROSS-REFERENCE TO RELATED APPLICATION

The priority application number JP2010-077201, nitride-based semiconductor laser device, Mar. 30, 2010, Takashi Kano, upon which this patent application is based is hereby incorporated by reference.

### BACKGROUND OF THE INVENTION

1. Field of the Invention

The present invention relates to a nitride-based semiconductor laser device including various layers made of nitride-based semiconductors.

2. Description of the Background Art

A nitride-based semiconductor laser device emitting a violet laser beam (wavelength: at least about 400 nm and not more than about 410 nm) is known in general, as disclosed in Japanese Patent Laying-Open No. 2006-229171, for example.

An exemplary structure of a conventional nitride-based semiconductor laser device is briefly described. In the nitride-based semiconductor laser device described in Japanese Patent Laying-Open No. 2006-229171, an n-side nitride-based semiconductor layer, an active layer and a p-side nitride-based semiconductor layer are successively stacked on an n-type GaN substrate. The p-side nitride-based semiconductor layer has a ridge portion (waveguide), and a p-side electrode is formed on the ridge portion of the p-side nitride-based semiconductor layer. An n-side electrode is formed on the back surface of the n-type GaN substrate.

The n-side nitride-based semiconductor layer is an n-type cladding layer made of n-type AlGaN or the like, and the p-side nitride-based semiconductor layer is a p-type cladding layer made of p-type AlGaN or the like. The active layer includes a well layer and a barrier layer both made of InGaN, while In compositions in the well layer and the active layer are different from each other.

In the conventional nitride-based semiconductor laser device, the p-type cladding layer is generally doped with Mg, which is a p-type impurity. If Mg is employed as the p-type impurity doped into the p-type cladding layer, however, the p-type cladding layer disadvantageously serves as a layer absorbing light (wavelength: at least about 400 nm and not more than about 410 nm) from the active layer. Therefore, the p-type cladding layer absorbs light seeping out of the active layer into the p-type cladding layer, thereby increasing light loss. Therefore, threshold current is increased and slope efficiency is reduced, and hence it is difficult for the nitride-based semiconductor laser device to obtain a higher output.

### SUMMARY OF THE INVENTION

A nitride-based semiconductor laser device according to an aspect of the present invention includes an active layer made of a nitride-based semiconductor and a p-type cladding layer, made of a nitride-based semiconductor, formed on the active layer. The refractive index in a region of the p-type cladding layer closer to the active layer is lower than the refractive index in another region of the p-type cladding layer opposite to the active layer.

### BRIEF DESCRIPTION OF THE DRAWINGS

FIG. 1 is a sectional view of a nitride-based semiconductor laser device according to a first embodiment of the present invention;

FIG. 2 is a graph showing the relation between an Al composition ratio and a refractive index in AlGaN with respect to light having a wavelength of 405 nm;

FIG. 3 illustrates refractive indices and optical density levels in respective layers of the nitride-based semiconductor laser device according to the first embodiment of the present invention;

FIG. 4 illustrates refractive indices and optical density levels in respective layers of a nitride-based semiconductor laser device according to comparative example;

FIGS. 5 to 8 are sectional views for illustrating a method of manufacturing the nitride-based semiconductor laser device according to the first embodiment of the present invention;

FIG. 9 is a diagram for illustrating the structure (refractive indices of respective layers) of a nitride-based semiconductor laser device according to a second embodiment of the present invention;

FIG. 10 is a diagram for illustrating the structure (refractive indices of respective layers) of a nitride-based semiconductor laser device according to a third embodiment of the present invention;

FIG. 11 is a diagram for illustrating the structure (refractive indices of respective layers) of a nitride-based semiconductor laser device according to a fourth embodiment of the present invention;

FIG. 12 is a diagram for illustrating the structure (refractive indices of respective layers) of a nitride-based semiconductor laser device according to a fifth embodiment of the present invention; and

FIG. 13 is a diagram for illustrating the structure (refractive indices of respective layers) of a nitride-based semiconductor laser device according to a sixth embodiment of the present invention.

### DESCRIPTION OF THE PREFERRED EMBODIMENTS

### First Embodiment

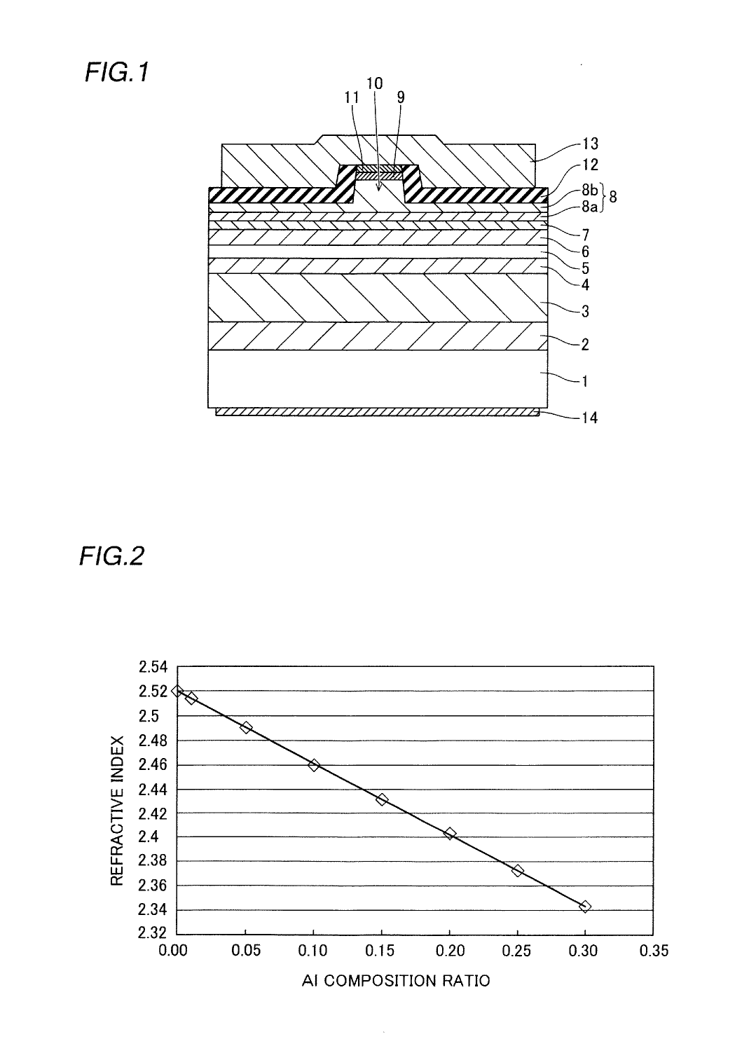

First, the structure of a nitride-based semiconductor laser device according to a first embodiment of the present invention is described with reference to FIG. 1. The nitride-based semiconductor laser device according to the first embodiment emits a violet laser beam (wavelength: at least about 400 nm and not more than about 410 nm), and is employed for an optical disk system or the like, for example.

In the nitride-based semiconductor laser device according to the first embodiment, a buffer layer 2 of undoped Al_{0.01}Ga_{0.99}N having a thickness of about 1.0 μm is formed on an n-type GaN substrate 1 having a thickness of about 100 μm, as shown in FIG. 1.

An n-type cladding layer 3 is formed on the buffer layer 2. The n-type cladding layer 3 confines light in an active layer 5 described later and increases the electron density in the active layer 5. An optical guiding layer 4 for confining light in the active layer 5 along with the n-type cladding layer 3 is formed on the n-type cladding layer 3. The n-type cladding layer 3 is made of n-type Al_{0.04}Ga_{0.96}N doped with Si serving as an n-type impurity, and has a thickness of about 2.5 μm. The optical guiding layer 4 is made of undoped In_{0.01}Ga_{0.99}N, and has a thickness of about 50 nm.

The active layer 5 emitting light by recombining injected carriers is formed on the optical guiding layer 4. The active layer 5 has a multiple quantum well (MQW) structure including well layers (about 7 nm in thickness each) made of InₓGa₁₋ₓN and barrier layers (about 20 nm in thickness each) of In_{y}Ga_{1-y}N alternately stacked one by one with each other. In composition ratios (In contents in InGaN) in the well layers and the barrier layers are different from each other, and x>y.

Another optical guiding layer 6 for confining light in the active layer 5 is formed on the active layer 5. Further, a cap layer 7 is formed on the optical guiding layer 6, to inhibit electrons from overflowing. The optical guiding layer 6 is made of undoped In_{0.01}Ga_{0.99}N, and has a thickness of about 70 nm. The cap layer 7 is made of undoped Al_{0.2}Ga_{0.8}N, and has a thickness of about 20 nm.

A p-type cladding layer 8 for confining light in the active layer 5 along with the optical guiding layer 6 and increasing hole density in the active layer 5 is formed on the cap layer 7. The p-type cladding layer 8 has a projecting portion, and a contact layer 9 made of undoped In_{0.07}Ga_{0.93}N is formed on the projecting portion of the p-type cladding layer 8 with a thickness of about 3 nm. A ridge portion 10 including the projecting portion of the p-type cladding layer 8 and the contact layer 9 serves as a waveguide. The structure of the p-type cladding layer 8 is described later in detail.

A p-side electrode 11 prepared by successively stacking a Pt layer and a Pd layer is formed on the ridge portion 10. A current blocking layer 12 made of SiO₂ is formed on planar portions of the p-type cladding layer 8, to extend onto the side surfaces of the ridge portion 10. A pad electrode 13 prepared by successively stacking a Ti layer and an Au layer is formed on the current blocking layers 12, to come into contact with the upper surface of the p-side electrode 11 through an opening of the current blocking layer 12. Further, an n-side electrode 14 prepared by stacking a Ti layer, a Pt layer and an Au layer in this order from the side of the n-type GaN substrate 1 is formed on the back surface of the n-type GaN substrate 1.

According to the first embodiment, the p-type cladding layer 8 is formed by a p-type AlGaN layer doped with Mg serving as the p-type impurity, and the Al composition ratio (Al content in AlGaN) therein is so controlled that the refractive index in a region of the p-type cladding layer 8 closer to the active layer 5 is lower than that in another region of the p-type cladding layer 8 opposite to the active layer 5.

More specifically, the p-type cladding layer 8 is constituted of a two-layer laminate including a lower p-type layer (formed on the cap layer 7) 8a closer to the active layer 5 and an upper p-type layer (formed on the lower p-type layer 8a) 8b closer to the contact layer 9 opposite to the active layer 5. In other words, the region of the p-type cladding layer 8 closer to the active layer 5 is constituted of the lower p-type layer 8a, while the region of the p-type cladding layer 8 opposite to the active layer 5 is constituted of the upper p-type layer 8b. The thickness of the lower p-type layer 8a is set to about 0.15 μm, and the thickness of the upper p-type layer 8b is set to about 0.35 μm. The thickness of the lower p-type layer 8a is set to be substantially constant from one side surface toward the other side surface of the projecting portion (ridge portion 10) of the p-type cladding layer 8. In this case, the thickness of the lower p-type layer 8a is more preferably set to be substantially constant from one side surface toward the other side surface of the nitride-based semiconductor laser device in the width direction. Therefore, the projecting portion of the p-type cladding layer 8 serving as the ridge portion 10 is formed only on a part of the upper p-type layer 8b. The lower p-type layer 8a is an example of the “first p-type layer” in the present invention, and the upper p-type layer 8b is an example of the “second p-type layer” in the present invention.

Both of the lower p-type layer 8a and the upper p-type layer 8b are made of p-type AlGaN doped with Mg, and the Al composition ratios in the lower p-type layer 8a and the upper p-type layer 8b are different from each other. More specifically, the lower p-type layer 8a is made of p-type Al_{0.07}Ga_{0.93}N, while the upper p-type layer 8b is made of p-type Al_{0.04}Ga_{0.96}N. In other words, the Al composition ratio (0.07) in the lower p-type layer 8a is set to be higher than the Al composition ratio (0.04) in the upper p-type layer 8b.

When the Al composition ratio (0.07) in the lower p-type layer 8a is set to be higher than the Al composition ratio (0.04) in the upper p-type layer 8b in the aforementioned manner, the refractive index in the lower p-type layer 8a is lower than that in the upper p-type layer 8b since the relation between the Al composition ratio and the refractive index in AlGaN with respect to light having a wavelength of about 405 nm is as shown in FIG. 2 (the refractive index is increased if the Al composition ratio is reduced, and vice versa). Thus, the refractive index in the region of the p-type cladding layer 8 closer to the active layer 5 is lower than that in the region of the p-type cladding layer 8 opposite to the active layer 5. This state is continuous from one side surface toward the other side surface of the nitride-based semiconductor laser device in the width direction. Therefore, the refractive index in the part of the p-type layer 8a located under the ridge portion 10 is lower than that in the p-type layer 8b provided with the ridge portion 10. The nitride-based semiconductor laser device according to the first embodiment is formed in the aforementioned manner.

A method of manufacturing the nitride-based semiconductor laser device according to the first embodiment is now described with reference to FIGS. 1 and 5 to 8.

In order to manufacture the nitride-based semiconductor laser device according to the first embodiment, the buffer layer 2 of undoped Al_{0.01}Ga_{0.99}N is first grown on the n-type GaN substrate 1 with the thickness of about 1.0 μm by metal organic chemical vapor deposition (MOCVD), as shown in FIG. 5. At this time, NH₃ gas, TMGa gas and TMAl gas are supplied as source gas.

Then, SiH₄ gas containing Si serving as an n-type impurity is further supplied in addition to NH₃ gas, TMGa gas and TMAl gas serving as the source gas, thereby growing the n-type cladding layer 3 made of n-type Al_{0.04}Ga_{0.96}N doped with Si on the buffer layer 2 with the thickness of about 2.5 μm. Thereafter NH₃ gas, TMGa gas and TMIn gas are supplied as source gas, thereby growing the optical guiding layer 4 made of undoped In_{0.01}Ga_{0.99}N on the n-type cladding layer 3 with the thickness of about 50 nm.

Then, NH₃ gas, TMGa gas and TMIn gas are supplied as source gas, thereby alternately growing the well layers (about 7 nm in thickness each) made of InₓGa₁₋ₓN and the barrier layers (about 20 nm in thickness each) of In_{y}Ga_{1-y}N one by one on the optical guiding layer 4. Thus, the active layer 5 of the MQW structure including the well layers and the barrier layers is formed on the optical guiding layer 4.

Then, NH₃ gas, TMGa gas and TMIn gas are supplied as source gas, thereby growing the optical guiding layer 6 made of undoped In_{0.01}Ga_{0.99}N on the active layer 5 with the thickness of about 70 nm. Thereafter NH₃ gas, TMGa gas and TMAl gas are supplied as source gas, thereby forming the cap layer 7 made of undoped Al_{0.2}Ga_{0.8}N on the optical guiding layer 6 with the thickness of about 20 nm.

Then, Cp₂Mg gas containing Mg serving as a p-type impurity is further supplied in addition to NH₃ gas, TMGa gas and TMAl gas serving as source gas, thereby growing the lower p-type layer 8a made of p-type Al_{0.07}Ga_{0.93}N on the cap layer 7 with the thickness of about 0.15 μm, and growing the upper p-type layer 8b made of p-type Al_{0.04}Ga_{0.96}N on the lower p-type layer 8a with the thickness of about 0.35 μm. In other words, the p-type cladding layer 8 consisting of the two-layer laminate including the lower p-type layer 8a and the upper p-type layer 8b is grown on the cap layer 7. Thus, the p-type cladding layer 8 is so obtained that the Al composition ratio in the region closer to the active layer 5 is higher than that in the region opposite to the active layer 5. Consequently, the refractive index in the region of the p-type cladding layer 8 closer to the active layer 5 is lower than that in the region of the p-type cladding layer 8 opposite to the active layer 5.

Thereafter NH₃ gas, TMGa gas and TMIn gas are supplied as source gas, thereby growing the contact layer 9 made of undoped In_{0.07}Ga_{0.93}N on the p-type cladding layer 8 with the thickness of about 3 nm.

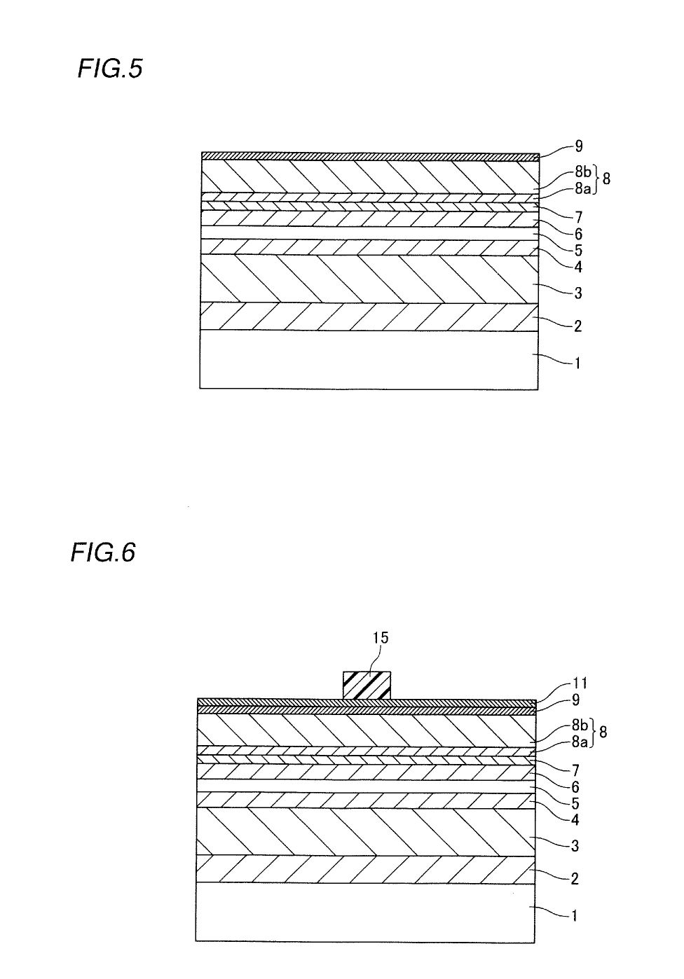

After the respective nitride-based semiconductor layers (2 to 9) are grown on the n-type GaN substrate 1, the p-side electrode 11 prepared by successively stacking the Pt layer and the Pd layer is formed on the contact layer 9 by vacuum evaporation, as shown in FIG. 6. Further, a resist layer 15 is formed on a ridge portion forming region (corresponding to the ridge portion 10 shown in FIG. 1) of the p-side electrode 11.

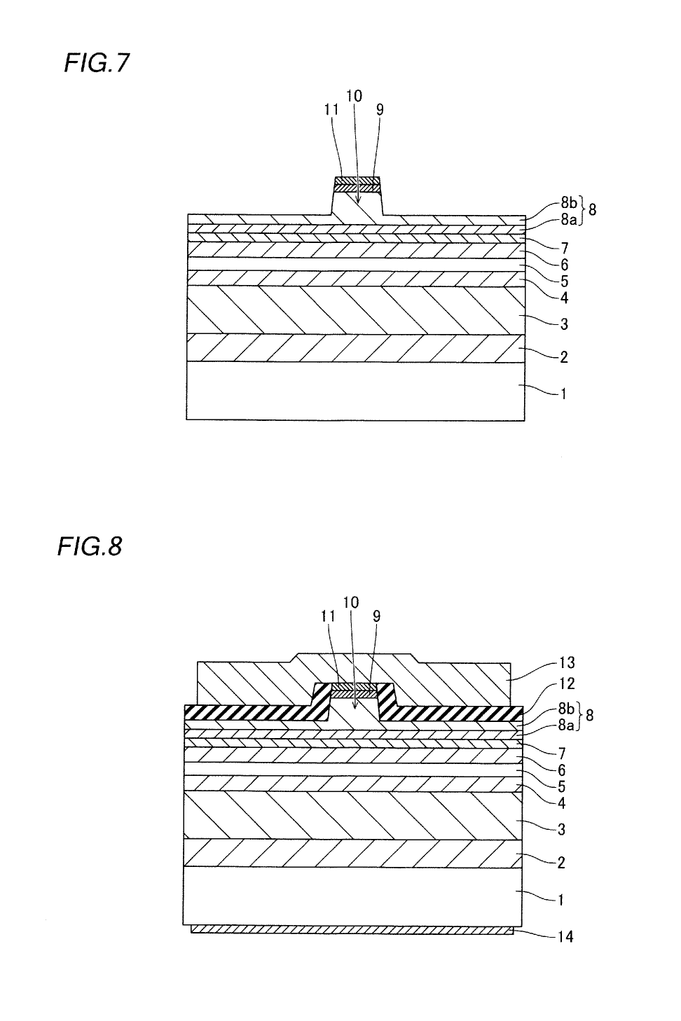

The resist layer 15 is employed as a mask for etching the p-side electrode 11, thereby entirely removing regions of the p-side electrode 11 other than the ridge portion forming region (projecting portion). Then, the resist layer 15 is employed as a mask for etching the contact layer 9 and the p-side cladding layer 8, thereby entirely removing regions of the contact layer 9 other than the ridge portion forming region while removing regions of the p-type cladding layer 8 other than the ridge portion forming region up to an intermediate depth. Thereafter the resist layer 15 is removed. Thus, the ridge portion 10 consisting of the projecting portion of the p-type cladding layer 8 and the contact layer 9 is obtained as shown in FIG. 7, so that the p-side electrode 11 is arranged only on the ridge portion 10.

Then, the overall surface closer to the ridge portion 10 is covered with an SiO₂ film by plasma CVD, and a region of the SiO₂ film superposed on the upper surface of the p-side electrode 11 is removed, thereby forming the current blocking layer 12 having the opening exposing the upper surface of the p-side electrode 11, as shown in FIG. 8. Thereafter the pad electrode 13 is formed on the current blocking layer 12 by vacuum evaporation, to be in contact with the upper surface of the p-side electrode 11 through the opening of the current blocking layer 12. In order to form the pad electrode 13, the Ti layer and the Au layer are successively stacked.

Then, the back surface of the n-type GaN substrate 1 is polished, to set the thickness of the n-type GaN substrate 1 to about 10 μm. Then, the Ti layer, the Pt layer and the Au layer are stacked on the back surface of the n-type GaN substrate 1 by vacuum evaporation in this order from the side of the n-type GaN substrate 1. Thus, the n-side electrode 14 is formed on the back surface of the n-type GaN substrate 1, as shown in FIG. 1.

Finally, device division is performed, thereby manufacturing the nitride-based semiconductor laser device according to the first embodiment.

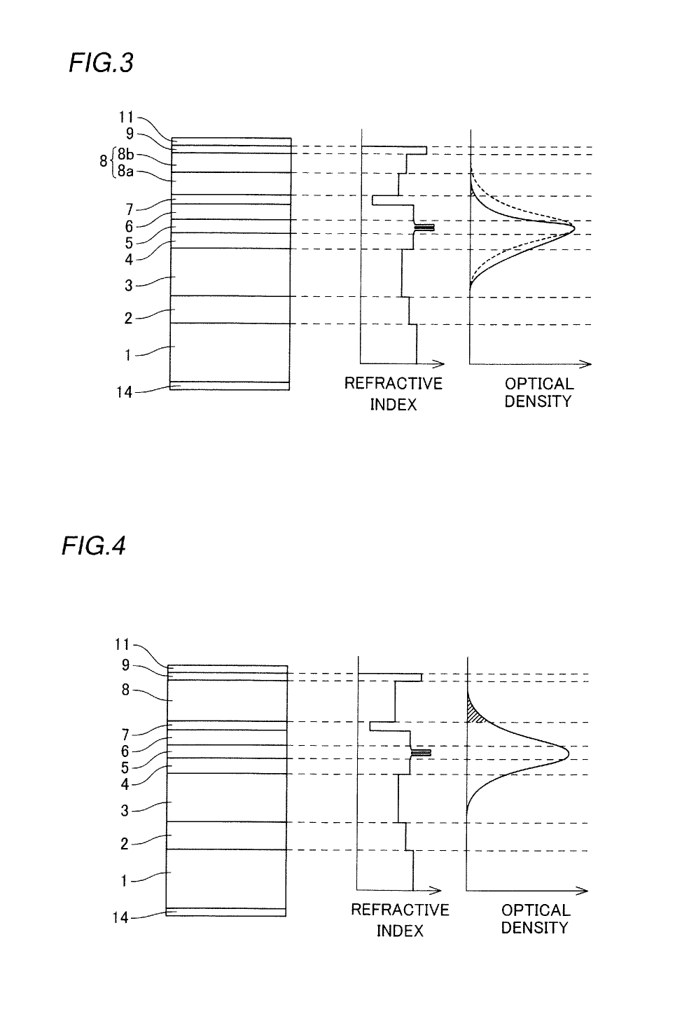

According to the first embodiment, as hereinabove described, the refractive index in the region (lower p-type layer 8a) of the p-type cladding layer 8 closer to the active layer 5 is set to be lower than that in the region (upper p-type layer 8b) of the p-type cladding layer 8 opposite to the active layer 5. Thus, the region (low refractive index region) of the p-type cladding layer 8 closer to the active layer 5 serves as a light seeping inhibition region inhibiting light from seeping out of the active layer 5, whereby the quantity of light (in a hatched region in FIG. 3) seeping out of the active layer 5 into the p-type cladding layer 8 is reduced, as shown in FIG. 3. Even if the p-type cladding layer 8 absorbs light from the active layer 5, therefore, the quantity of light seeping out of the active layer 5 into the p-type cladding layer 8 itself is reduced, whereby light absorption (light loss) in the p-type cladding layer 8 is reduced. If the region of the p-type cladding layer 8 closer to the active layer 5 is not formed as the light seeping inhibition region (low refractive index region), the quantity of light (in a hatched region in FIG. 4) seeping out of the active layer 5 into the p-type cladding layer 8 is increased as in comparative example shown in FIG. 4, to disadvantageously increase light absorption (light loss) in the p-type cladding layer 8.

Thus, the refractive index in the region (lower p-type layer 8a) of the p-type cladding layer 8 closer to the active layer 5 is so set to be lower than that in the region (upper p-type layer 8b) of the p-type cladding layer 8 opposite to the active layer 5 that threshold current is reduced, slope efficiency is improved and driving current is reduced following the improvement of the slope efficiency, whereby the nitride-based semiconductor laser device can obtain a higher output.

According to the first embodiment, one region of the p-type cladding layer 8 is employed as the light seeping inhibition region (low refractive index region), whereby the light seeping inhibition region (low refractive index region) formed by the lower p-type layer 8a exerts the essential function of the p-type cladding layer 8. In other words, reduction in hole injection efficiency from the p-type cladding layer 8 into the active layer 5 is suppressed. If an undoped layer (not doped with Mg) having a thickness capable of blocking seeping of light is employed for inhibiting light from seeping out of the active layer 5 into the p-type cladding layer 8, the undoped layer inhibits hole injection from the p-type cladding layer 8 into the active layer 5, and hence the hole injection efficiency from the p-type cladding layer 8 into the active layer 5 is disadvantageously reduced.

According to the first embodiment, as hereinabove described, the Al composition ratio in the region (lower p-type layer 8a) of the p-type cladding layer 8 closer to the active layer 5 is set to be higher than that in the region (upper p-type layer 8b) of the p-type cladding layer 8 opposite to the active layer 5, whereby the refractive index in the region of the p-type cladding layer 8 closer to the active layer 5 can be easily set to be lower than that in the region of the p-type cladding layer 8 opposite to the active layer 5.

According to the first embodiment, the Al composition ratio in the region, i.e., the upper p-type layer 8b, of the p-type cladding layer 8 opposite to the active layer 5 is not higher than that in the lower p-type layer 8a, and hence specific resistance and contact resistance of the p-type cladding layer 8 are not much increased. Thus, operating voltage of the nitride-based semiconductor laser device can be kept unincreased.

According to the first embodiment, as hereinabove described, the p-type cladding layer 8 has the two-layer structure including the lower p-type layer 8a and the upper p-type layer 8b. Thus, the refractive index in the region of the p-type cladding layer 8 closer to the active layer 5 can be easily set to be lower than that in the region of the p-type cladding layer 8 opposite to the active layer 5 by forming the lower and upper p-type layers 8a and 8b so that the refractive index in the lower p-type layer 8a is lower than that in the upper p-type layer 8b.

According to the first embodiment, as hereinabove described, both of the lower and upper p-type layers 8a and 8b are made of AlGaN, whereby the light seeping inhibition region inhibiting light from seeping out of the active layer 5 can be easily formed in the p-type cladding layer 8 made of the nitride-based semiconductor.

According to the first embodiment, as hereinabove described, the nitride-based semiconductor laser device includes the ridge portion 10 formed on the p-type cladding layer 8, and the refractive index in the part of the lower p-type layer 8a located under the ridge portion 10 is lower than that in the upper p-type layer 8b in the region provided with the ridge portion 10. Thus, in the region of the nitride-based semiconductor laser device provided with the waveguide, the region (low refractive index region) of the p-type cladding layer 8 closer to the active layer 5 can be formed as the light seeping inhibition region inhibiting light from seeping out of the active layer 5. In other words, light absorption (light loss) in the p-type cladding layer 8 can be reduced on the waveguide. Consequently, the threshold current of the nitride-based semiconductor laser device can be effectively reduced.

According to the first embodiment, as hereinabove described, the thickness of the lower p-type layer 8a is set to be substantially constant at least from one side surface toward the other side surface of the ridge portion 10. Therefore, the light seeping inhibition region inhibiting light from seeping out of the active layer 5 can be arranged on the overall region of the part of the lower p-type layer 8a located under the ridge portion 10 at least including the region provided with the ridge portion 10. Thus, light absorption (light loss) in the p-type cladding layer 8 can be reliably reduced on the waveguide.

### Second Embodiment

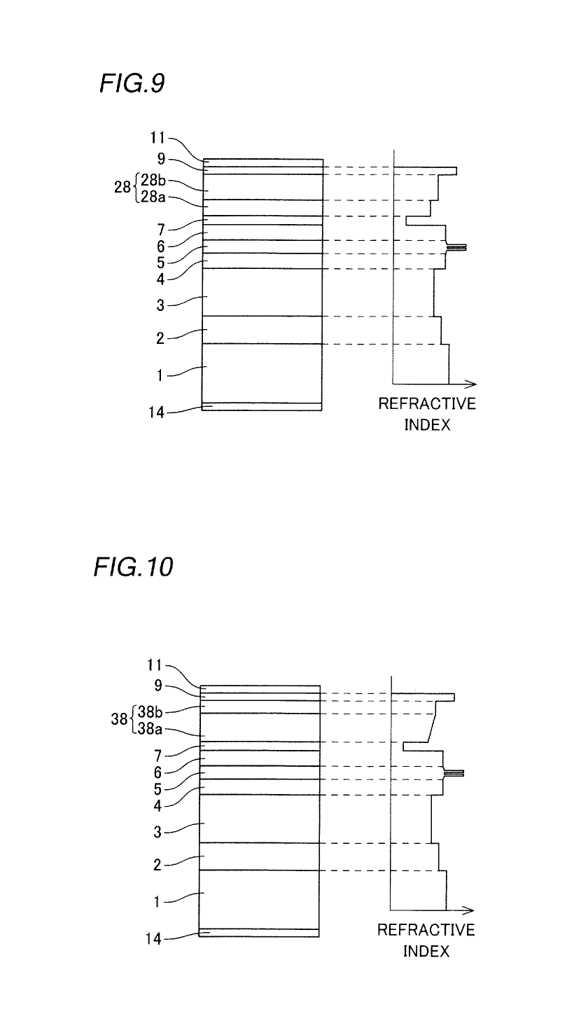

The structure of a nitride-based semiconductor laser device according to a second embodiment of the present invention is now described with reference to FIG. 9.

The nitride-based semiconductor laser device according to the second embodiment is substantially similar in structure to the nitride-based semiconductor laser device according to the first embodiment. A p-type cladding layer 28 made of p-type AlGaN doped with Mg is formed on a cap layer 7, and has a two-layer structure (including a lower p-type layer 28a and an upper p-type layer 28b).

According to the second embodiment, further, the Al composition ratio in the lower p-type layer 28a is set to be higher than that in the upper p-type layer 28b similarly to the first embodiment, so that the refractive index in a region of the p-type cladding layer 28 closer to an active layer 5 is lower than that in another region of the p-type cladding layer 28 opposite to the active layer 5. The lower p-type layer 28a is made of Al_{0.2}Ga_{0.8}N, while the upper p-type layer 28b is made of Al_{0.05}Ga_{0.95}N.

According to the second embodiment, the thickness of the lower p-type layer 28a is extremely reduced as compared with the first embodiment, so that the upper p-type layer 28b has a larger thickness. More specifically, the thickness of the lower p-type layer 28a is about 10 nm, while the thickness of the upper p-type layer 28b is about 0.50 μm. The lower and upper p-type layers 28a and 28b are examples of the “first p-type layer” and the “second p-type layer” in the present invention respectively.

While the thickness of the lower p-type layer 28a is extremely reduced, the second embodiment having the aforementioned structure can attain effects similar to those of the first embodiment.

### Third Embodiment

The structure of a nitride-based semiconductor laser device according to a third embodiment of the present invention is now described with reference to FIG. 10.

The nitride-based semiconductor laser device according to the third embodiment is substantially similar in structure to the nitride-based semiconductor laser device according to the first embodiment. A p-type cladding layer 38 of a two-layer structure (including a lower p-type layer 38a and an upper p-type layer 38b) is formed on a cap layer 7, and the lower and upper p-type layers 38a and 38b included in the p-type cladding layer 38 are made of p-type AlGaN doped with Mg. The lower and upper p-type layers 38a and 38b are examples of the “first p-type layer” and the “second p-type layer” in the present invention respectively.

The nitride-based semiconductor laser device according to the third embodiment is similar to the nitride-based semiconductor laser device according to the first embodiment in a point that the Al composition ratio in the lower p-type layer 38a is set to be higher than that in the upper p-type layer 38b, and different from the nitride-based semiconductor laser device according to the first embodiment in a point that the Al composition ratio in the lower p-type layer 38a is slopingly changed.

More specifically, the Al composition ratio (0.035) in the upper p-type layer 38b is constant over the entire region in the thickness direction, and the upper p-type layer 38b is made of Al_{0.035}Ga_{0.965}N. On the other hand, the Al composition ratio in the lower p-type layer 38a gradually decreases from 0.2 to 0.035 as separated from a region (side of the lower surface of the lower p-type layer 38a) closer to an active layer 5 toward another region opposite to the active layer 5. In other words, the region of the lower p-type layer 38a closer to the active layer 5 is made of Al_{0.2}Ga_{0.8}N similarly to the cap layer 7, while the region of the lower p-type layer 38a opposite to the active layer 5 is made of Al_{0.035}Ga_{0.965}N similarly to the upper p-type layer 38b. Thus, the refractive index gradually increases in the lower p-type layer 38a from the region closer to the cap layer 8 toward the region closer to the upper p-type layer 38b.

The thickness of the lower p-type layer 38a is about 0.05 μm, while the thickness of the upper p-type layer 38b is about 0.45 μm.

According to the third embodiment, effects similar to those of the first embodiment can be attained due to the aforementioned structure, while strain resulting from the lattice constant difference between the lower p-type layer 38a and the upper p-type layer 38b can also be suppressed.

According to the third embodiment, as hereinabove described, the Al composition ratio in the p-type cladding layer 38 is changed in the lower p-type layer 38a so that the refractive index in the lower p-type layer 38a increases substantially at a constant ratio as separated from the side closer to the active layer 5 toward the side opposite to the active layer 5 to reach the refractive index of the upper p-type layer 38b. Thus, a light seeping inhibition region inhibiting light from seeping out of the active layer 5 can be formed by the lower p-type layer 38a whose refractive index is reliably changed (to increase) while suppressing strain resulting from lattice constant difference in the p-type cladding layer 38.

According to the third embodiment, as hereinabove described, the nitride-based semiconductor laser device includes the cap layer 7 of Al_{0.2}Ga_{0.8}N formed between the active layer 5 and the lower p-type layer 38a, and the Al composition ratio (0.2) in the lower p-type layer 38a in the vicinity of a contact interface between the same and the cap layer 7 is substantially equal to the Al composition ratio in the cap layer 7, while the Al composition ratio (0.035) in the lower p-type layer 38a in the vicinity of a contact interface between the same and the upper p-type layer 38b is substantially equal to the Al composition ratio in the upper p-type layer 38b. Thus, the Al composition ratio in the lower and upper p-type layers 38a and 38b can be continuously changed (to decrease) from the cap layer 7 to the upper p-type layer 38b through the lower p-type layer 38a, whereby strain resulting from lattice constant difference can be easily suppressed in the p-type cladding layer 38.

### Fourth Embodiment

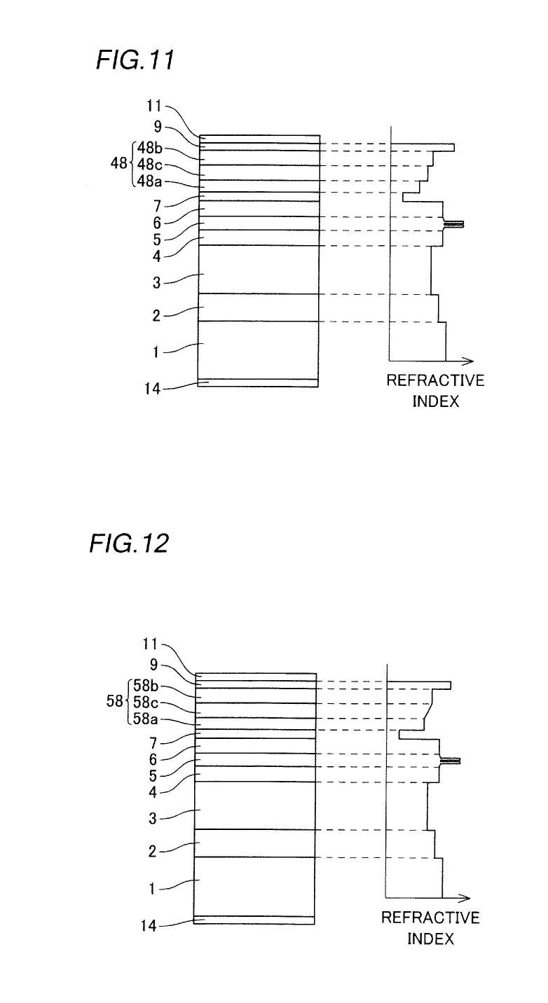

The structure of a nitride-based semiconductor laser device according to a fourth embodiment of the present invention is now described with reference to FIG. 11.

In the nitride-based semiconductor laser device according to the fourth embodiment, a p-type cladding layer 48 of a three-layer structure (including a lower p-type layer 48a, an upper p-type layer 48b and an intermediate p-type layer 48c) is formed on a cap layer 7, dissimilarly to the first embodiment. The lower, upper and intermediate p-type layers 48a, 48b and 48c included in the p-type cladding layer 48 are made of p-type AlGaN doped with Mg. The lower, upper and intermediate p-type layers 48a, 48b and 48c are examples of the “first p-type layer”, the “second p-type layer” and the “third p-type layer” in the present invention respectively.

According to the fourth embodiment, the lower p-type layer 48a is made of Al_{0.08}Ga_{0.92}N while the upper p-type layer 48b is made of Al_{0.04}Ga_{0.96}N, so that the Al composition ratio (0.08) in the lower p-type layer 48a is higher than the Al composition ratio (0.04) in the upper p-type layer 48b and the refractive index in a region of the p-type cladding layer 48 closer to an active layer 5 is lower than that in another region of the p-type cladding layer 48 opposite to the active layer 5. The fourth embodiment is similar to the first embodiment in this point.

In addition to this, the intermediate p-type layer 43c provided between the lower p-type layer 48a and the upper p-type layer 48b is made of Al_{0.06}Ga_{0.94}N in the nitride-based semiconductor laser device according to the fourth embodiment. In other words, the intermediate p-type layer 48c having the Al composition ratio (0.06) between the Al composition ratio (0.08) in the lower p-type layer 48a and the Al composition ratio (0.04) in the upper p-type layer 48b is held between the lower p-type layer 48a and the upper p-type layer 48b.

The thicknesses of the lower p-type layer 48a, the upper p-type layer 48b and the intermediate p-type layer 48c are about 0.10 μm, about 0.20 μm and about 0.10 μm respectively.

According to the fourth embodiment, the nitride-based semiconductor laser device has the aforementioned structure, whereby effects similar to those of the first embodiment are attained, and strain resulting from lattice constant difference between the lower p-type layer 48a and the upper p-type layer 48b can be suppressed due to the function of the intermediate p-type layer 48c. Further, the intermediate p-type layer 48c is made of AlGaN, whereby the same can be made of the same nitride-based semiconductor as the lower and upper p-type layers 48a and 48b. Therefore, the p-type cladding layer 48 of a multilayer structure including regions different refractive indices along the thickness direction can be reliably formed.

### Fifth Embodiment

The structure of a nitride-based semiconductor laser device according to a fifth embodiment of the present invention is now described with reference to FIG. 12.

The structure of the nitride-based semiconductor laser device according to the fifth embodiment is substantially similar to that of the nitride-based semiconductor laser device according to the fourth embodiment. A p-type cladding layer 58 of a three-layer structure (including a lower p-type layer 58a, an upper p-type layer 58b and an intermediate p-type layer 58c) is formed on a cap layer 7, and the lower, upper and intermediate p-type layer 58a, 58b and 58c included in the p-type cladding layer 58 are made of p-type AlGaN doped with Mg. The lower p-type layer 58a is made of Al_{0.15}Ga_{0.85}N while the upper p-type layer 58b is made of Al_{0.035}Ga_{0.965}N, so that the Al composition ratio (0.15) in the lower p-type layer 58a is higher than the Al composition ratio (0.035) in the upper p-type layer 58b. The lower, upper and intermediate p-type layer 58a, 58b and 58c are examples of the “first p-type layer”, the “second p-type layer” and the “third p-type layer” in the present invention respectively.

According to the fifth embodiment, the Al composition ratios in the lower p-type layer 58a and the upper p-type layer 58b are set to be constant over the entire regions while the Al composition ratio in the intermediate p-type layer 58c is slopingly changed, dissimilarly to the fourth embodiment. More specifically, the Al composition ratio in the intermediate p-type layer 58c gradually decreases from 0.15 to 0.035 from a region closer to an active layer 5 toward another region opposite to the active layer 5. In other words, the region of the intermediate p-type layer 58c closer to the active layer 5 is made of Al_{0.15}Ga_{0.85}N similarly to the lower p-type layer 58a, while the region of the intermediate p-type layer 58c opposite to the active layer 5 is made of Al_{0.035}Ga_{0.965}N similarly to the upper p-type layer 58b. Thus, the refractive index in the intermediate p-type layer 58c gradually increases from the region closer to the lower p-type layer 58a toward the region closer to the upper p-type layer 58b.

The thicknesses of the lower p-type layer 58a, the upper p-type layer 58b and the intermediate p-type layer 58c are about 0.03 μm, about 0.38 μm and about 0.05 μm respectively.

According to the fifth embodiment, the nitride-based semiconductor laser device has the aforementioned structure, whereby effects similar to those of the first embodiment can be attained, and strain resulting from lattice constant difference between the lower p-type layer 58a and the upper p-type layer 58b can be further suppressed due to the function of the intermediate p-type layer 58c.

According to the fifth embodiment, as hereinabove described, both of the Al composition ratios in the lower and upper p-type layers 58a and 58b are substantially constant along the thickness direction of the p-type cladding layer 58, while the Al composition ratio in the intermediate p-type layer 58c is changed to gradually decrease from the side closer to the lower p-type layer 58a toward the side closer to the upper p-type layer 58b. Thus, strain resulting from the lattice constant difference between the lower and upper p-type layers 58a and 58b can be reliably suppressed due to the intermediate p-type layer 58c arranged between the lower and upper p-type layers 58a and 58b.

### Sixth Embodiment

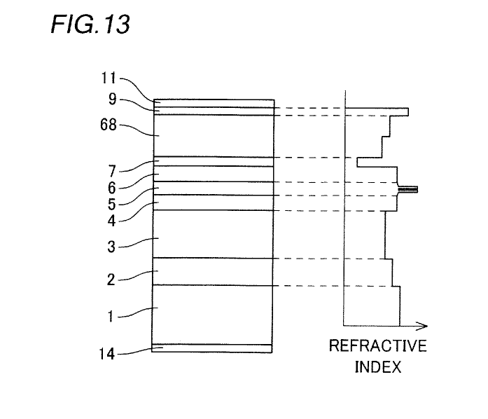

The structure of a nitride-based semiconductor laser device according to a sixth embodiment of the present invention is now described with reference to FIG. 13.

In the nitride-based semiconductor laser device according to the sixth embodiment, a p-type cladding layer 68 made of p-type AlGaN doped with Mg is formed on a cap layer 7, similarly to the first embodiment.

According to the sixth embodiment, however, the p-type cladding layer 68 has not a multilayer structure but a single-layer structure, dissimilarly to the first embodiment. The Al composition ratio in a region of the p-type cladding layer 68 closer to an active layer 5 is set to be higher than that in another region of the p-type cladding layer 68 opposite to the active layer 5. Thus, the refractive index in the region of the p-type cladding layer 68 closer to the active layer 5 is lower than that in the region of the p-type cladding layer 68 opposite to the active layer 5.

According to the sixth embodiment, the nitride-based semiconductor laser device has the aforementioned structure, whereby effects similar to those of the first embodiment can be attained although the p-type cladding layer 68 does not have a multilayer structure.

Although the present invention has been described and illustrated in detail, it is clearly understood that the same is by way of illustration and example only and is not to be taken by way of limitation, the spirit and scope of the present invention being limited only by the terms of the appended claims.

For example, while the p-type cladding layer is doped with Mg serving as the p-type impurity in each of the aforementioned embodiments, the present invention is not restricted to this. According to the present invention, the p-type cladding layer may alternatively be doped with a p-type impurity other than Mg.

In the structure of the nitride-based semiconductor laser device according to each of the aforementioned embodiments, the Al composition ratios in the regions of the p-type cladding layer closer to and opposite to the active layer respectively may alternatively be changed. When the Al composition ratio in the region of the p-type cladding layer opposite to the active layer is at least 0.01 and not more than 0.15, however, the difference between the Al composition ratios in the regions of the p-type cladding layer closer to and opposite to the active layer respectively is preferably in the range of at least 0.002 and not more than 0.2. Particularly when the Al composition ratio in the region of the p-type cladding layer opposite to the active layer is at least 0.03 and not more than 0.1, the difference between the Al composition ratios in the regions of the p-type cladding layer closer to and opposite to the active layer respectively is more preferably in the range of at least 0.005 and not more than 0.2.

When the Al composition ratio in the region (upper p-type layer) of the p-type cladding layer opposite to the active layer is set to 0.04, for example, the Al composition ratio in the region (lower p-type layer) of the p-type cladding layer closer to the active layer is preferably higher than that in the region (upper p-type layer) of the p-type cladding layer opposite to the active layer in the range of at least 0.002 and not more than 0.20, and more preferably in the range of at least 0.005 and not more than 0.20.

In the structure of the nitride-based semiconductor laser device according to each of the aforementioned embodiments, the thicknesses of the regions of the p-type cladding layer closer to and opposite to the active layer respectively may alternatively be changed. However, the thickness of the region (lower p-type layer) of the p-type cladding layer closer to the active layer is preferably in the range of at least 2% and not more than 80% of the thickness of the overall p-type cladding layer, and more preferably in the range of at least 6% and not more than 60% of the thickness of the overall p-type cladding layer. In particular, the thickness of the region (lower p-type layer) of the p-type cladding layer closer to the active layer is most preferably in the range of at least 10% and not more than 50% of the thickness of the overall p-type cladding layer.

When the total thickness of the p-type cladding layer is set to about 0.5 μm, for example, the thickness of the region (lower p-type layer) of the p-type cladding layer closer to the active layer is preferably at least 10 nm and not more than 400 nm, and more preferably at least about 30 nm and not more than 300 nm. Further, the thickness of the region of the p-type cladding layer closer to the active layer is most preferably at least about 50 nm and not more than about 250 nm.

What is claimed is:

1. A nitride-based semiconductor laser device comprising:
an active layer made of a nitride-based semiconductor; and
a p-type cladding layer, made of a nitride-based semiconductor, formed on said active layer, wherein
the refractive index in a region of said p-type cladding layer closer to said active layer is lower than the refractive index in another region of said p-type cladding layer opposite to said active layer.

2. The nitride-based semiconductor laser device according to claim 1, wherein
said p-type cladding layer is made of a nitride-based semiconductor containing Al, and
the Al composition ratio in said region of said p-type cladding layer closer to said active layer is higher than the Al composition ratio in said region of said p-type cladding layer opposite to said active layer.

3. The nitride-based semiconductor laser device according to claim 2, wherein
the difference between the Al composition ratio in said region of said p-type cladding layer closer to said active layer and the Al composition ratio in said region of said p-type cladding layer opposite to said active layer is in the range of at least 0.002 and not more than 0.2 when the Al composition ratio in said region of said p-type cladding layer opposite to said active layer is at least 0.01 and not more than 0.15.

4. The nitride-based semiconductor laser device according to claim 3, wherein
the difference between the Al composition ratio in said region of said p-type cladding layer closer to said active layer and the Al composition ratio in said region of said p-type cladding layer opposite to said active layer is in the range of at least 0.005 and not more than 0.2 when the Al composition ratio in said region of said p-type cladding layer opposite to said active layer is at least 0.03 and not more than 0.1.

5. The nitride-based semiconductor laser device according to claim 2, wherein
the Al composition ratio in said p-type cladding layer is changed to gradually decrease in said region of said p-type cladding layer closer to said active layer as separated from the surface closer to said active layer toward said region of said p-type cladding layer opposite to said active layer.

6. The nitride-based semiconductor laser device according to claim 5, wherein
the Al composition ratio in said p-type cladding layer is so changed that the refractive index in said p-type cladding layer increases at a substantially constant ratio in said region of said p-type cladding layer closer to said active layer as separated from the side closer to said active layer toward the side opposite to said active layer.

7. The nitride-based semiconductor laser device according to claim 1, wherein
said p-type cladding layer is constituted of a laminate, formed by successively stacking a plurality of p-type layers each made of a nitride-based semiconductor from the side of said active layer,
said region of said p-type cladding layer closer to said active layer is constituted of a first p-type layer, included in said plurality of p-type layers, positioned closer to said active layer, and
said region of said p-type cladding layer opposite to said active layer is constituted of a second p-type layer, included in said plurality of p-type layers, positioned on the side opposite to said active layer.

8. The nitride-based semiconductor laser device according to claim 7, wherein
said first p-type layer and said second p-type layer are made of a nitride-based semiconductor containing Al, and
the Al composition ratio in said first p-type layer is higher than the Al composition ratio in said second p-type layer.

9. The nitride-based semiconductor laser device according to claim 8, wherein
the Al composition ratio in said second p-type layer is substantially constant in the thickness direction of said p-type cladding layer, and
the Al composition ratio in said first p-type layer is changed to gradually decrease from the side closer to said active layer toward said second p-type layer.

10. The nitride-based semiconductor laser device according to claim 8, wherein
said first p-type layer and said second p-type layer are made of AlGaN.

11. The nitride-based semiconductor laser device according to claim 9, further comprising a cap layer, made of a nitride-based semiconductor containing Al, formed between said active layer and said first p-type layer, wherein
the Al composition ratio in said first p-type layer in the vicinity of the contact interface between said first p-type layer and said cap layer is substantially equal to the Al composition ratio in said cap layer, and
the Al composition ratio in said first p-type layer in the vicinity of the contact interface between said first p-type layer and said second p-type layer is substantially equal to the Al composition ratio in said second p-type layer.

12. The nitride-based semiconductor laser device according to claim 8, wherein
said p-type cladding layer further includes a third p-type layer, made of a nitride-based semiconductor containing Al, arranged between said first p-type layer and said second p-type layer in addition to said first p-type layer and said second p-type layer, and
the Al composition ratio in said third p-type layer is lower than the Al composition ratio in said first p-type layer and higher than the Al composition ratio in said second p-type layer.

13. The nitride-based semiconductor laser device according to claim 12, wherein
said third p-type layer is made of AlGaN.

14. The nitride-based semiconductor laser device according to claim 12, wherein
the Al composition ratios in said first p-type layer and said second p-type layer are both substantially constant in the thickness direction of said p-type cladding layer, and
the Al composition ratio in said third p-type layer is changed to gradually decrease from the side closer to said first p-type layer toward said second p-type layer.

15. The nitride-based semiconductor laser device according to claim 1, wherein
the thickness of said region of said p-type cladding layer closer to said active layer is set to at least 2% and not more than 80% with respect to the total thickness of said p-type cladding layer.

16. The nitride-based semiconductor laser device according to claim 15, wherein
the thickness of said region of said p-type cladding layer closer to said active layer is set to at least 6% and not more than 60% with respect to the total thickness of said p-type cladding layer.

17. The nitride-based semiconductor laser device according to claim 16, wherein
the thickness of said region of said p-type cladding layer closer to said active layer is set to at least 10% and not more than 50% with respect to the total thickness of said p-type cladding layer.

18. The nitride-based semiconductor laser device according to claim 1, wherein
a p-type impurity doped into said p-type cladding layer is Mg.

19. The nitride-based semiconductor laser device according to claim 1, further comprising a ridge portion formed on said p-type cladding layer for constituting a waveguide, wherein
the refractive index in a portion of said p-type cladding layer under said ridge portion is lower than the refractive index in a region of said p-type cladding layer provided with said ridge portion.

20. The nitride-based semiconductor laser device according to claim 19, wherein
the thickness of said region of said p-type cladding layer closer to said active layer is substantially constant at least from one side surface to the other side surface of said ridge portion.
